(19) United States
(12) Patent Application Publication
(10) Pub. No.: US 2006/0065962 A1
(43) Pub. Date: Mar. 30, 2006

(54) Control circuitry in stacked silicon

(75) Inventors: Siva G. Narendra, Portland, OR (US); James W. Tschanz, Portland, OR (US); Vivek K. De, Beaverton, OR (US); Shekhar Borkar, Beaverton, OR (US)

Correspondence Address: SCHWABE, WILLIAMSON & WYATT, PACWEST CENTER, SUITE 1900, 1211 S.W. FIFTH AVE., PORTLAND, OR, 97204, US

(73) Assignee: Intel Corporation

(21) Appl. No.: 10/954,256

(22) Filed: Sep. 29, 2004

(51) Int. Cl. H01L 23/02

(52) U.S. Cl. 257/686

(57) ABSTRACT

Apparatus, system and method for managing power of a main circuitry disposed on a main substrate using a control circuitry disposed on a control substrate, in a stacked relationship with the main substrate, are described herein.

### FIELD OF THE INVENTION

Embodiments of the present invention in general relate to the field of semiconductor circuitry. More specifically, embodiments of the present invention relate to power management of semiconductor circuitry.

### BACKGROUND INFORMATION

Ever since the invention of integrated circuits, the drive toward a higher integration level has been relentless. However, one limiting factor of the continuing drive to a higher integration level is power consumption. As circuits become highly integrated, a significant portion of total power consumption is due to leakage, such as through sub-threshold conduction, junction leakage, and tunneling through the gate oxide.

One solution to this problem is to use a sleep transistor to dynamically alter voltage applied to a circuit in accordance to idleness of the circuit. The use of sleep transistors though also has drawbacks. First, sleep transistors require additional conductive (e.g. metal) pathways that may already be in short supply in a circuit. Second, adding sleep transistors may affect a circuit design schedule and possibly cause manufacturing delays. Finally, incorporating sleep transistors increases complexity of a circuit and may require increased die size to accommodate a large number of sleep transistors.

### BRIEF DESCRIPTION OF DRAWINGS

Embodiments of the present invention will be described by way of exemplary embodiments, but not limitations, illustrated in the accompanying drawings in which like references denote similar elements, and in which:

FIG. 1 is a schematic showing a stacked control substrate with a main substrate according to one embodiment;

FIG. 2 is a schematic showing an alternatively stacked control substrate with a main substrate according to one embodiment;

FIG. 3 is a schematic showing an alternatively stacked control substrate with a main substrate according to one embodiment;

FIG. 4 is a schematic showing an alternatively stacked control substrate with a main substrate according to one embodiment;

FIG. 5 is a circuit diagram showing a coupled control circuitry with a main circuitry according to one embodiment;

FIG. 6 is a circuit diagram showing a coupled control circuitry with a main circuitry according to another embodiment;

FIG. 7 is a circuit diagram showing a coupled control circuitry with a main circuitry according to one embodiment;

FIG. 8 is a block diagram showing a system according to one embodiment;

FIG. 9 is a flow diagram showing a method of coupling a control circuitry with a main circuitry according to one embodiment;

FIG. 10 is a flow diagram showing a method of stacking two substrates according to one embodiment;

FIG. 11 is a flow diagram showing an alternative method of stacking two substrates according to one embodiment.

FIG. 12 is a flow diagram showing an operational method of stacked substrates according to one embodiment.

### DETAILED DESCRIPTION

Various aspects of the illustrative embodiments will be described using terms commonly employed by those skilled in the art to convey the substance of their work to others skilled in the art. However, it will be apparent to those skilled in the art that alternate embodiments may be practiced with only some of the described aspects. For purposes of explanation, specific numbers, materials, and configurations are set forth in order to provide a thorough understanding of the illustrative embodiments. However, it will be apparent to one skilled in the art that alternate embodiments may be practiced without the specific details. In other instances, well-known features are omitted or simplified in order not to obscure the illustrative embodiments. The terms “comprising”, “having” and “including” are synonymous, unless the context dictates otherwise.

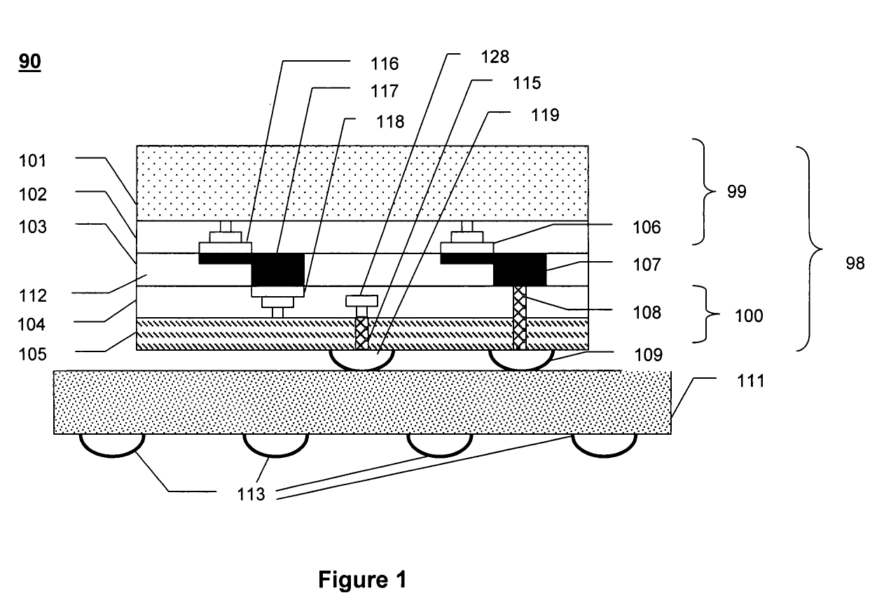

FIG. 1 shows a schematic 90 of a stacked substrate 98 including a main substrate 99 and a control substrate 100 in accordance with one embodiment. As illustrated, for the embodiment, the main substrate 99 and the control substrate 100 may be jointed at a redirect layer 103 to effectuate an electrical connection between circuits contained on both substrates.

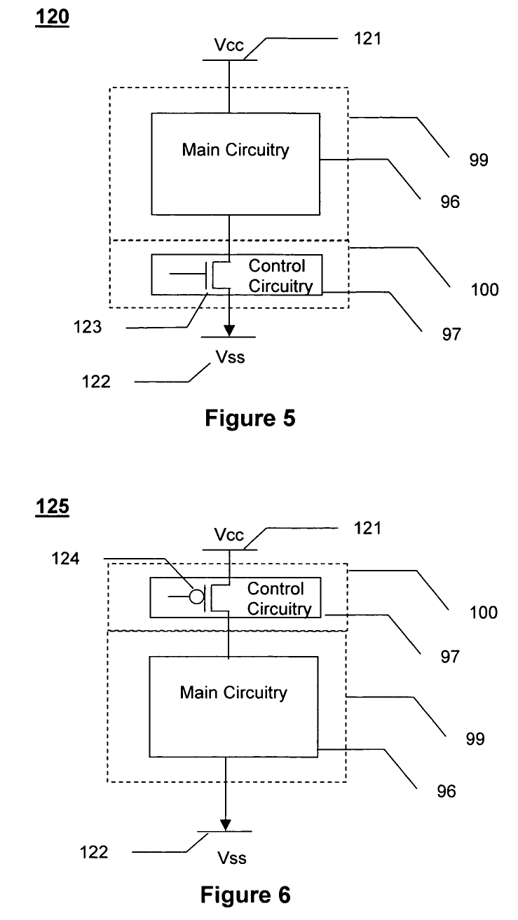

The main substrate 99 may contain a main circuitry 96 (shown in FIG. 5), that may be, but is not limited to, a processor circuitry, a logic controller circuitry, an integrated circuitry, and a memory circuitry. An example of a main circuitry 96 may be a Celeron® D processor circuitry produced by Intel Corp., Santa Clara, Calif.

The main substrate 99 may contain two layers: a main semiconductor layer 101 and a main interconnect layer 102. The main semiconductor layer 101 may contain various types of components such as Metal Oxide Semiconductor (MOS) transistors, Complementary Metal Oxide Semiconductors (CMOS), bipolar transistors, diodes, or any combination thereof. The main interconnect layer 102 may contain from six to nine layers of conducting pathways used to distribute power and signals for the main circuitry 96. As an illustration, three layers are shown in FIG. 1.

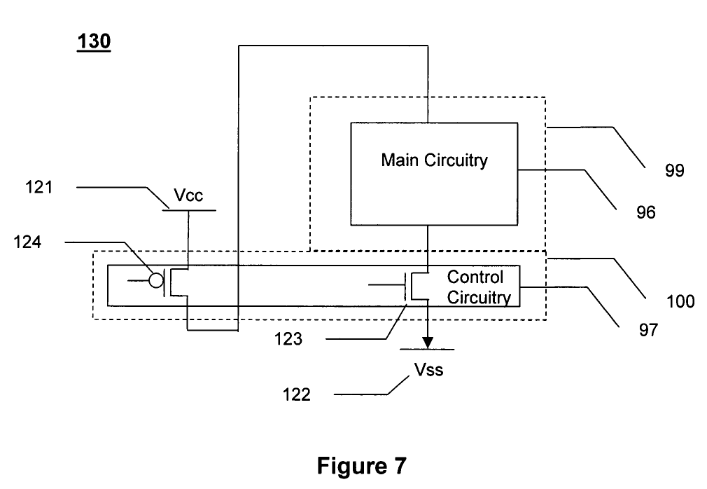

The control substrate 100 may contain a control circuitry 97 (shown in FIG. 5) adapted to perform power management function for the main circuitry 96. The control circuitry 97 may include a simple switching circuit, examples of which are described below with reference to FIGS. 5 and 6, or a combination of switching circuits, an example of which is described below with reference to FIG. 7. The control circuitry 97 may be used to control power flows to the entire main circuitry 96 or to each power block on the main circuitry 96. The control circuitry 97 may also contain other circuits such as, non-exclusively, clock cycle synchronizers, analog-to-digital converts, power filters, and surge suppressors.

The control substrate 100 may also contain two layers: a control semiconductor layer 105 and a control interconnect layer 104. The control semiconductor layer 105 may contain various types of components used in the circuits adapted to perform power management function for the main circuitry 96. An exemplary control semiconductor layer 105 may contain nMOS, pMOS, bipolar transistors, diodes, or a combination thereof. The control interconnect layer 104 may contain at least one layer of conducting pathways used to distribute power and signals for the control circuitry 97. The control substrate 100 may also contain one or more partial via 115 to connect circuitry located on the control semiconductor layer 105 to a connection point 119.

A redirect layer 103 may couple the main substrate 99 and the control substrate 100 such that the main circuitry 96 and the control circuitry 97 are electrically coupled. The redirect layer 103 may contain conductive pathways that connects bond pads 106 and 116 on the main substrate 99 to corresponding locations on the control substrate 100. For example, a redirect conductive pathway 117 may be used to connect bond pad 116 located on the main substrate 99 to a bond pad 118 located on the control substrate 100. The redirect pathway 117 may be in direct contact with the bond pad 118. A redirect conductive pathway 107 may connect bond pad 106 located on the main substrate 99 to a connection point 109 located on the control substrate 100 through a full via 108.

Optionally, there may be other via drilled through the control substrate 100 for directly connecting to circuits formed on the main semiconductor layer 101. For example, a particular logic circuit formed on the main semiconductor layer 101 might require power regulation and monitoring by a power circuit formed on a substrate external to the stacked substrate 98. The power circuit may be electrically connected to the logic circuit through a via such as a full via 108 and a connection point 109. The number of via may vary as is required by the circuit design.

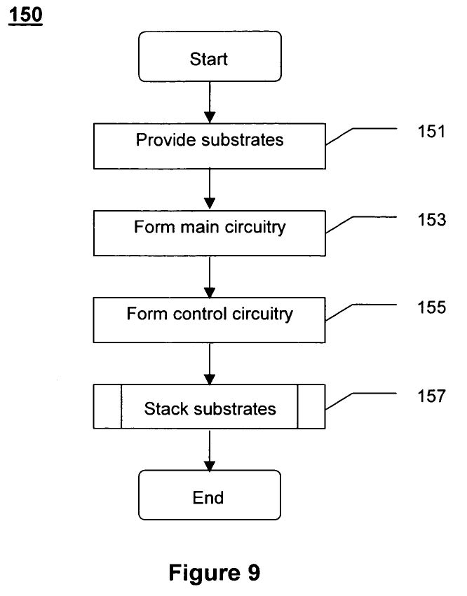

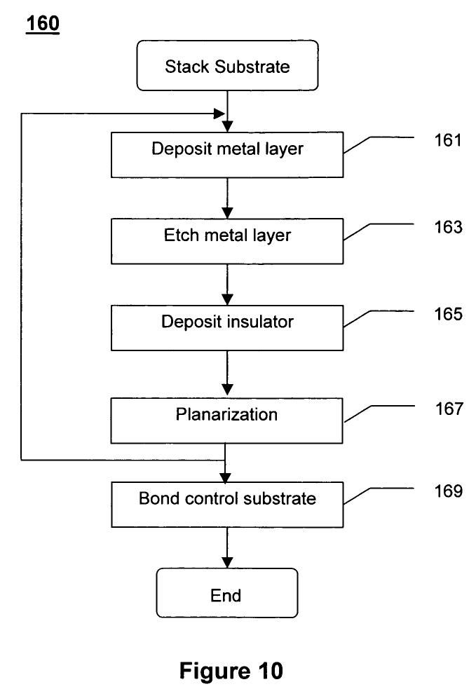

The redirect layer 103 may also contain an insulating layer 112 composed of, non-exclusively, silicon monoxide, silicon dioxide, and silicon nitrides. The redirect layer 103 may be deposited on the main substrate 99, and the control substrate 100 may be bonded to the redirect layer 103 at the control interconnect layer 104 to achieve electrical coupling, as further described below with reference to FIGS. 9 and 10.

The stacked control substrate 100 and main substrate 99 may be connected to a carrier substrate 1 1 1 via connection points 109 and 119. The carrier substrate 111 may provide power and electrical signals to both the main substrate 99 and control substrate 100. The carrier substrate may be, but is not limited to, a printed circuit board or an interposer. Typical connecting techniques include pin-through-hole connection (e.g. pin grid array (PGA)), Land Grid Array (LGA), and Flip Chip-Ball Grid Array (FC-BGA) packaging.

The carrier substrate 111 then may be connected to another circuit board, such as a mother board (not shown), via connection points 113 to obtain power and to perform communication with other components on the integrated circuit board. Connection points 113 may be, but are not limited to pins, Land Grid Array (LGA), or Ball Grid Array (BGA).

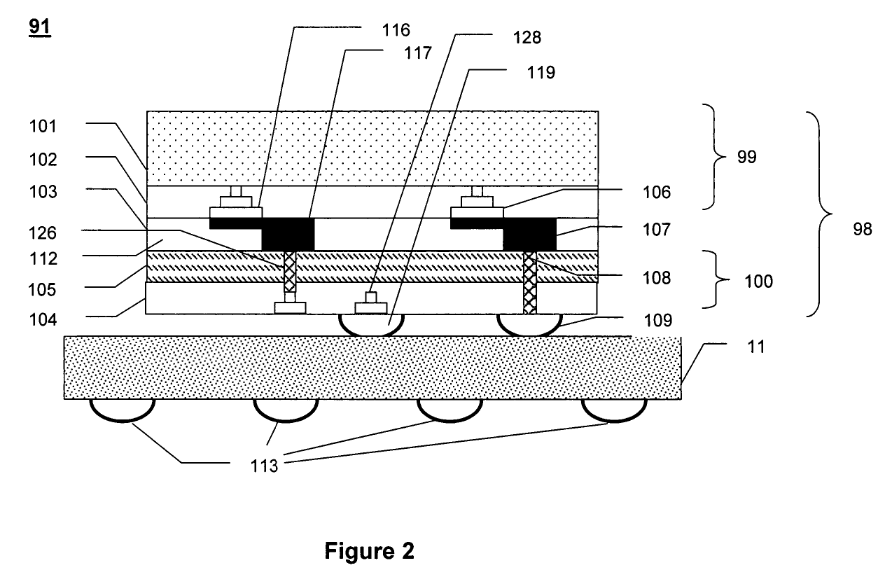

In an alternative embodiment, as is illustrated in FIG. 2, the main substrate 99 and control substrate 100 may be stacked by depositing the redirect layer 103 on the main substrate 99, and bonding the control substrate 100 to the redirect layer 103 at the control semiconductor layer 105. For example, a conductive pathway 117 may connect a bond pad 116 located on the main substrate 99 to, for example, the metal layers located on the control semiconductor layer 105 through a via 126. A bond pad 106 located on the main substrate 99 may be connected to a connection point 109 located on the control substrate 100 through a full via 108. Circuits located on the control substrate 100 may also connect to at least one connection point 119 through a conductive pathway 128. Similarly, there may be other partial or full vias between the main semiconductor layer 101 and the control semiconductor layer 105 for connecting circuits formed on the two layers.

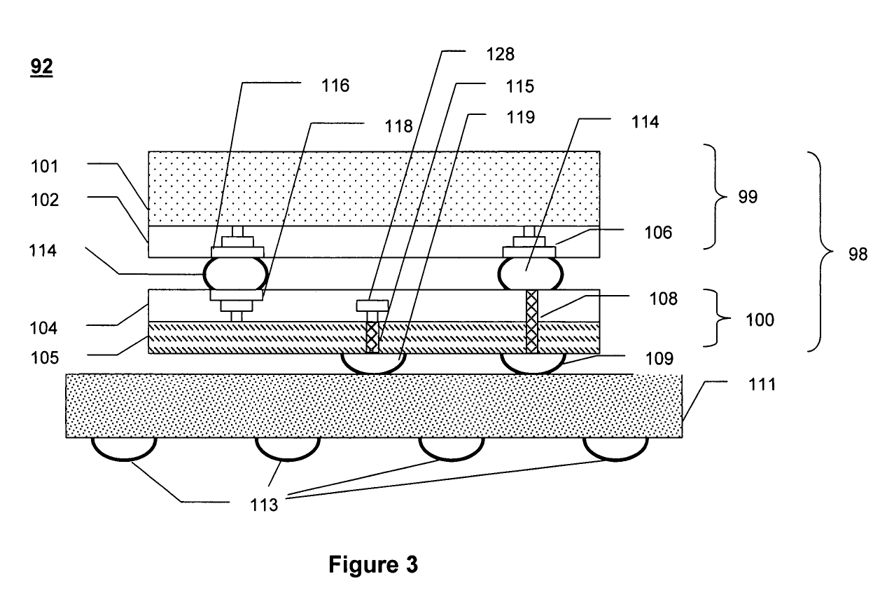

FIG. 3 shows another embodiment where a main substrate 99 and a control substrate 100 may be stacked without a redirect layer 103.

In the described embodiment, the main substrate 99 and the control substrate 100 may be stacked between a main interconnect layer 102 and a control interconnect layer 104 through a ball grid array 114. The ball grid array 114 may connect circuits located in the main semiconductor layer 101 to circuits located in the control semiconductor layer 105. For example, a bond pad 106 located on the main substrate 99 may be connected to a connection point 109 located on the control substrate 100 through a ball grid array 114 and a full via 108. A bond pad 116 located on the main substrate 99 may be connected to a bond pad 118 located on the control substrate 100 through the ball grid array 114. Other coupling techniques may also be used to stack the main substrate 99 with the control substrate 100 such as, non-exclusively, a Land Grid Array using dendritic, conductive elastomer, fuzz button, and metal spring. The control substrate 100 may also contain one or more partial via 115 to connect circuitry located on the control semiconductor layer 105 to at least one connection point 119.

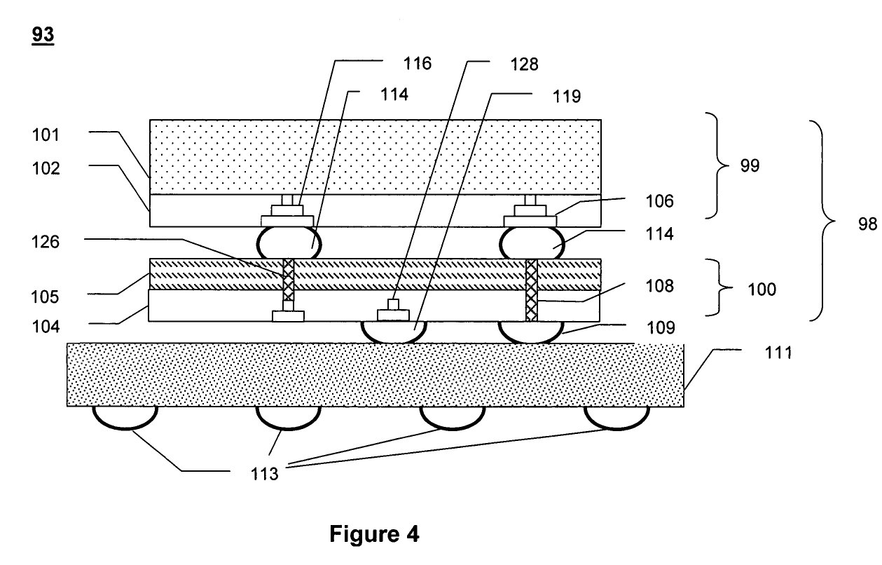

FIG. 4 shows yet another embodiment, where the main substrate 99 and the control substrate 100 are stacked between a main interconnect layer 102 and a control semiconductor layer 104 through a ball grid array 114.

In the described embodiment, the ball grid array 114 may connect circuits located in the main semiconductor layer 101 to circuits located in the control semiconductor layer 105. For example, a bond pad 106 located on the main substrate 99 may be connected to a connection point 109 located on the control substrate 100 through a full via 108. A bond pad 116 located on the main substrate 99 may be connected to circuit located on the control substrate 100 through the ball grid array 114 and a via 126. Other coupling techniques may also be used to stack the main substrate 99 with the control substrate 100 such as, non-exclusively, a Land Grid Array using dendritic, conductive elastomer, fuzz button, and metal spring.

FIG. 5 shows a circuit diagram 120 of another embodiment where the control circuitry 97 controls external ground 122 of the main circuitry 96. The control circuitry 97 may contain a nMOS transistor 123 located on the control substrate 100. In operation, when the main circuitry 96 is in use, the transistor 123 may be activated to allow power to flow from an external supply (Vcc) 121 through the main circuitry 96 to an external ground (Vss) 122. When the main circuitry 96 is idle, the transistor 123 may be deactivated to remove power applied to the main circuitry 96 in order to reduce power leakage in the main circuitry 96.

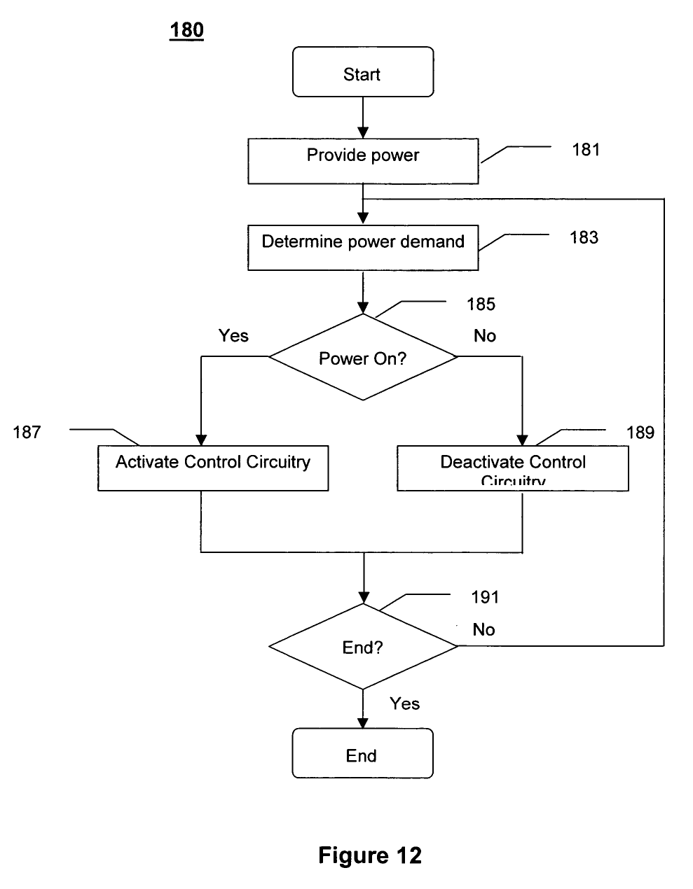

Alternatively, the control circuitry 97 may be used to control a portion of the main circuitry 96. For example, the control circuitry 97 may be connected to only the arithmetic and logic unit (ALU) of the main circuitry 96. In operation, the transistor 123 is activated or deactivated to control power applied to only the ALU without affecting other circuits of the main circuitry. The control circuitry 97 may also be connected to each power block in the main circuitry 96. For example, the control circuitry 97 may be connected to each power block in the ALU to regulate power applied to each block without affecting other blocks in the ALU. The operation of the control circuitry 97 is further described below with reference to FIG. 12.

FIG. 6 shows a circuit diagram 125 of another embodiment where the control circuitry 97 may control external power supply to the main and control circuits 121 of the main circuitry 96. In the described embodiment, the control circuitry may include a pMOS transistor 124 located on the control substrate 100. In operation, when the main circuitry 96 is in use, the transistor 124 may be activated, and power may be allowed to flow from the external power supply (Vcc) 121 through transistor 124 to the main circuitry 96. When the main circuitry 96 is idle, the transistor 124 may be deactivated to remove power applied to the main circuitry 96 in order to reduce power leakage in the main circuitry 96. Alternatively, the control circuitry 97 may be used to control a portion, or each power block of the main circuitry 96 as described above with reference to FIG. 5.

In yet another alternative embodiment, as illustrated in FIG. 7, a pMOS transistor 124 may control external power supply 121 and a nMOS transistor 123 may control external ground of the main circuitry 96, respectively. In operation, when the main circuitry 96 is in use, both nMOS transistor 123 and the pMOS transistor 124 may be activated to allow power to flow from the external supply (Vcc) 121 to the main circuitry 96 and then to the external ground (Vss) 122. When the main circuitry 96 is idle, one or both transistors 123 and 124 may be deactivated to remove power applied to the main circuitry 96 in order, among other reasons, to reduce power leakage in the main circuitry 96. Alternatively, the control circuitry 97 may be used to control a portion, or each power block of the main circuitry 96 as described above with reference to FIG. 5. In yet another embodiment, nMOS transistor 123 may be utilized to control a first portion of the main circuitry while pMOS transistor 124 may be utilized to control a second portion of the main circuitry.

For embodiments described with reference to FIGS. 5, 6 and 7, the control circuitry 97 may also contain other circuits such as, non-exclusively, clock cycle synchronizers, analog-to-digital converts, power filters, and surge suppressors.

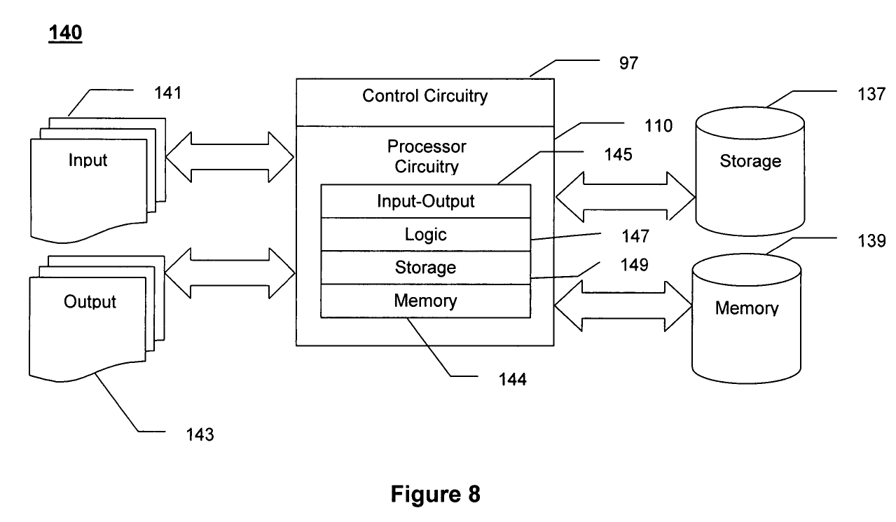

FIG. 8 is a functional block diagram 140 showing a system according to one embodiment. The system may include a processor circuitry 110 formed on a main substrate 99 (shown in FIG. 1-4) that is coupled with a control circuitry 97 formed on a control substrate 100 (shown in FIG. 1-4), as described above with reference to FIGS. 14. The control circuitry 97 may perform power management for the processor circuitry 110, as further described below with reference to FIG. 12.

The processor circuitry 110 may typically include, but is not limited to, an input-output 145, arithmetic and logic 147, an on-chip non-persistent storage 149, and a memory 144. The memory 139 provides additional temporary off-chip non-persistent storage, which may be used during processor operation. The input-output 145 may facilitate the processor circuitry 110 to receive signals from input 141, and the processor circuitry 110 may process the received signals into output 143 according to instructions residing in memory 139. The input 141 may include, but is not limited to, keyboard input, mouse input, sound input, video input, digiPad input, and tablet input. The output 143 may include but are not limited to, graphics display, media output, electronic signal output, and printer output.

Optionally, persistent mass data storage 137 may be coupled to the processor circuitry 110 to provide non-volatile data storage. For example, the processor circuitry 110 may store output 143 in the data storage 137, or may retrieve data from data storage 137 for processing. The persistent mass data storage 137 may be, but is not limited to, a hard drive, a flash memory card, a Secured Digital card, a CD-ROM drive, and a DVD drive.

FIG. 9 is a flow diagram 150 showing a method of coupling a control circuitry with a main circuitry, in accordance with a further embodiment. As an initial operation, a main and a control substrate may be provided (block 151). Next, a main circuitry 96 may be formed on the main substrate 99 (block 153). The formation typically may include processes such as silicon base material preparation; photoresist material deposition, stepper exposure, chemical or plasma etch, and resist removal. Depending on different main circuitry 96 desired, the above mentioned processing techniques might be applied repeatedly.

Then, the control circuitry 97 may be formed on the control substrate 100 (block 155). In the described embodiment, the control circuitry 97 may include one CMOS device constructed from one nMOS transistor and one pMOS transistor. An exemplary process for manufacturing such a circuit may include defining active areas, etching and filling trenches, implanting well regions, depositing and patterning polysilicon layer, implanting source and drain and substrate contacts, creating contact and via windows, and depositing and patterning interconnect layers. Alternatively, the control circuitry 97 may contain a plurality of nMOS and/or pMOS transistors, which may be formed onto the control substrate 100 with similar processes.

After preparing both the main and control circuitry, the main and the control substrates may be stacked to effectuate an electrical coupling between the main and control circuitry. In one embodiment, the two substrates may be stacked through a Controlled Collapse Chip Connection (C4) process using ball grid arrays as shown in FIG. 4 and 5. The control circuitry 97 may be coupled to the main circuitry 96 and to an external ground (Vss) 129, as is illustrated in FIG. 5. The control circuitry 97 may be coupled to the main circuitry 96 and to an external power supply (Vcc) 121, as illustrated in FIG. 6. The control circuitry 97 may also be coupled to the main circuitry 96 and to both an external power supply and a ground, as illustrated in FIG. 7. Alternatively, the main and control substrates may be stacked at a redirect layer 103 as further described below with reference to FIG. 10. In addition, other methods of stacking the main substrate 99 and the control substrate 100 may also be used, such as a LGA technique using dendritic, conductive elastomer, fuzz button, and metal springs.

FIG. 10 shows a method of stacking the main substrate 99 and control substrate 100, in accordance with a further embodiment. As an initial operation, a conductive layer may be deposited on the main interconnect layer 102 (block 161). The conductive layer may then be etched to form a first layer of the conductive pathways 107 and 117 (block 163). Then, an insulating layer 112 may be deposited on the first layer of the conductive pathways 107 and 117 (block 165). Materials suitable to be used in the insulating layer 112 include, but are not limited to, silicon monoxide, silicon dioxide, and silicon nitrides. Then, the main substrate 99 may be planarized using techniques such as Chemical-Mechanical Planarization, Boron-Doped Phosphosilicate Glass, and Spin on Glass to expose the first layer of the conductive pathways 107 and 117 (block 167). Then, depending on desired patterns, multiple layers of the conductive pathways 107 and 117 may be deposited following similar processes for connecting bond pads located on the main substrate 99 to corresponding locations on the control substrate 100. In the described embodiment, two layers may be used as illustrated in FIG. 1 and FIG. 2.

Then, the control substrate 100 may be bonded to the insulating layer 112 at the control interconnect layer 104 (block 169), as illustrated in FIG. 1. Alternatively, the control substrate 100 may be bonded to the insulating layer 112 at the control semiconductor layer 105, as illustrated in FIG. 2. The bonding of control substrate 100 to the insulating layer 112 may be performed using, non-exclusively, polymer adhesives and metal bonding.

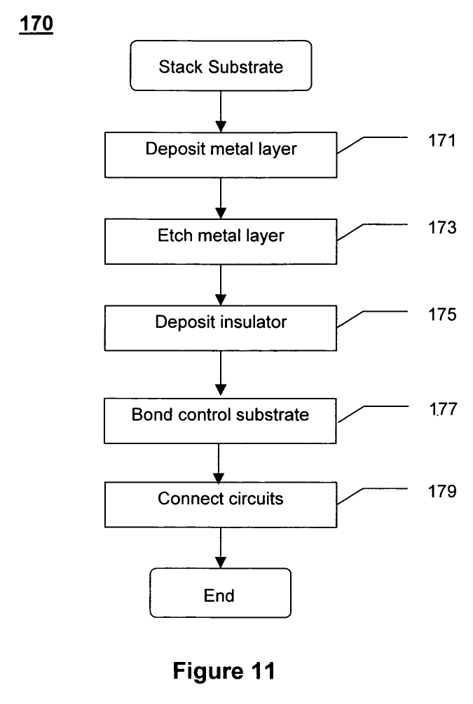

Alternatively, a single conductive layer may be used as conductive pathways 107 and 117 as illustrated in FIG. 11. In the described embodiment, a conductive layer may be deposited on the main interconnect layer 102 (block 171). The conductive layer may then be etched to form the conductive pathways 107 and 117 (block 173). Then, an insulating layer 112 may be deposited on the first layer of the conductive pathways 107 and 117 to insulate the conductive pathways 107 and 117 as well as the main interconnect layer 102 from the control substrate 100 (block 175). The main substrate 99 may then be planarized before bonding using techniques such as, non-exclusively, Chemical-Mechanical Planarization, Boron-Doped Phosphosilicate Glass, and Spin on Glass.

Then, the control substrate 100 may be bonded to the insulating layer 112 at the control interconnect layer 104 (block 177), as illustrated in FIG. 1. Alternatively, the control substrate 100 may be bonded to the insulating layer 112 at the control semiconductor layer 105, as illustrated in FIG. 2. The bonding of control substrate 100 to the insulating layer 112 may be performed using, non-exclusively, polymer adhesives and metal bonding.

After the control substrate 100 is bonded to the insulating layer 112, fall vias may be drilled through the control substrate 100 (block 179) to reach the conductive pathways 107 and 117. The full vias may electrically couple circuits located on the control substrate 100 to circuits located on the main substrate 99 through the conductive pathways 107 and 117. Also, partial vias, such as partial via 115 may be drilled to electrically contact metal layers 128 formed in the control metal layer 104. After drilling, these partial and full vias may be filled with an electrically conductive material.

FIG. 12 is a flow diagram showing an operational method 180 of the stacked substrates 99, in accordance with a further embodiment. As an initial operation, power may be provided to the stacked substrates at an external power supply (Vcc) 121 (block 181). Then, a power requirement of the main circuitry 96 or a portion of the main circuitry 96 may be determined (block 183). A timer circuitry formed on the control substrate 100 may be used to continuously monitor processing activities of the main circuitry 96. If the main circuitry 96 has not been active for a preset amount of time, the state of the timer circuitry is deemed to be “expired,” and the main circuitry 96 may be deemed to be idle based at least in part of the state of the timer circuitry.

Alternatively, the control circuitry 97 may be driven by a control block, which synchronizes the turn-on and turn-off of the main circuitry 96 with a signal external to the control circuitry 97, such as a clock-gating signal. In operation, a state of the external signal is continuously monitored for. When the external signal is present, as indicated by either an “on” or “off” state of the external signal, the main circuitry 96 is deemed to be non-idle, and vice versa. In addition, capability may be provided for overdriving or underdriving the control circuitry 97 to reduce frequency penalty. In an alternative embodiment, a circuit located on an independent substrate may be used to perform the power requirement determination for the main substrate 99. In yet another embodiment, both the timer circuitry and the external signal may be used in combination to determine idleness of the main circuitry 96.

After a power requirement is determined, a selection may be performed (block 185). If the monitored main circuitry 96 is idle, the control circuitry 97 may be deactivated (block 189) to remove power at either the external ground (Vss) 122, as is illustrated in FIG. 5; at the external power supply (Vcc) 121, as illustrated in FIG. 6, or at both external power supply (Vcc) 121 and ground (Vss) 122, as illustrated in FIG. 7. On the other hand, If the monitored circuitry is non-idle, the control circuitry 97 may be activated or maintained (block 187) to allow power to be provided to at least a portion of the main circuitry 96.

After activating or deactivating the control circuitry, a selection may be performed (block 191). If such power regulation is no longer needed, for example, the external power source may be removed, the process ends; otherwise, the process may revert back to determining power requirement (block 183) of the monitored circuitry.

Although specific embodiments have been illustrated and described herein, it will be appreciated by those of ordinary skill in the art that a wide variety of alternate and/or equivalent implementations may be substituted for the specific embodiments shown and described, without departing from the scope of the present invention. This application is intended to cover any adaptations or variations of the embodiments discussed herein. Therefore, it is manifestly intended that this invention be limited only by the claims and the equivalents thereof.

What is claimed is:

1. An apparatus, comprising:
a main substrate;
a main circuitry formed on the main substrate;
a control substrate stacked with the main substrate; and
a control circuitry formed on the control substrate, electrically coupled to the main circuitry, and adapted to perform power management for at least a portion of the main circuitry.

2. The apparatus of claim 1, wherein the control circuitry comprises at least one transistor electrically coupled to the main circuitry, and adapted to control power flow to at least a portion of the main circuitry.

3. The apparatus of claim 1, further comprising:
a carrier substrate electrically coupled to the control circuitry and adapted to provide power to the main circuitry via the control circuitry.

4. The apparatus of claim 1, wherein the control circuitry comprises a control semiconductor layer and at least one control interconnect layer coupled to the control semiconductor layer, and the main circuitry comprises a main semiconductor layer and at least one main interconnect layer coupled to the main semiconductor layer and the at least one control interconnect layer.

5. The apparatus of claim 4, wherein the control interconnect layer and the main interconnect layer are bonded to each other.

6. The apparatus of claim 5, wherein the control interconnect layer and the main interconnect layer are bonded using a ball grid array.

7. The apparatus of claim 4, wherein the control semiconductor layer and the main interconnect layer are bonded to each other.

8. The apparatus of claim 1, further comprising:
a redirect layer deposited on the main substrate, and bonded with the control substrate.

9. The apparatus of claim 8, wherein the redirect layer includes at least one conductive pathway and an insulating layer.

10. The apparatus of claim 1, wherein the control circuitry comprises a selected circuitry of a circuitry group consisting of a nMOS transistor coupled to an external ground of at least a portion of the main circuitry, a pMOS transistor coupled to an external supply voltage of at least a portion of the main circuitry, and a nMOS transistor and a pMOS transistor coupled to an external ground and an external supply voltage of at least a portion of the main circuitry, respectively.

11. The apparatus of claim 1, wherein the control circuitry is adapted to control power flow to the entire main circuitry or only a portion of the main circuitry.

12. The apparatus of claim 1, wherein the main circuitry is a selected circuitry of a circuitry group consisting of microprocessor circuitry, an integrated circuitry, a control logic circuitry, and a memory circuitry.

13. The apparatus of claim 1, wherein the control circuitry comprises a selected circuitry of a circuitry group consisting of a timer circuitry adapted to determine idleness of the main circuitry and a control block adapted to synchronize the activation and deactivation of the main circuitry based on an external signal.

14. A system, comprising:
a processor circuitry formed on a main substrate;
a memory electrically coupled to the processor circuitry;
a control substrate stacked with the main substrate;
a control circuitry formed on the control substrate and electrically coupled to the processor circuitry, the control circuitry is adapted to perform power management of at least a portion of the processor circuitry; and
a data storage device coupled to both the processor circuitry and the memory for providing persistent mass data memory.

15. The system of claim 14, further comprising:
an input device coupled and providing data to the processor circuitry; and
an output device coupled to and outputting data from the processor circuitry.

16. The system of claim 14, wherein the control circuitry comprises a selected circuitry of a circuitry group consisting of a nMOS transistor coupled to an external ground of at least a portion of the main circuitry, a pMOS transistor coupled to an external supply voltage of at least a portion of the main circuitry, and a nMOS transistor and a PMOS transistor coupled to an external ground and an external supply voltage of at least a portion of the main circuitry, respectively.

17. The system of claim 14, further comprising:
a redirect layer deposited on the main substrate, and bonded with the control substrate.

18. The system of claim 14, wherein the control circuitry comprises a selected circuitry of a circuitry group consisting of a timer circuitry adapted to determine idleness of the main circuitry and a control block adapted to synchronize the activation and deactivation of the main circuitry based on an external signal.

19. A method, comprising:
providing a main substrate;
forming a main circuitry on the main substrate;
providing a control substrate;
forming a control circuitry on the control substrate, the control circuitry being adapted to perform power management for at least a portion of the main circuitry; and
stacking the main substrate and the control substrate, including electrically coupling the control circuitry to the main circuitry for the performance of power management.

20. The method of claim 19, wherein said stacking comprises stacking the main substrate and the control substrate using a ball grid array.

21. The method of claim 19, further comprising:
forming at least one conductive pathway on the main substrate;
depositing an insulating layer on top of the at least one conductive pathway;
planarizing the main substrate to expose the at least one conductive pathway; and
bonding the control substrate to the at least one conductive pathway.

22. The method of claim 19, further comprising:
forming one conductive pathway on the main substrate;
depositing an insulating layer on top of the one conductive pathway;
planarizing the main substrate without exposing the one conductive pathway;
bonding the control substrate to the insulating layer; and
forming at least one via through the control substrate for electrically connecting the main circuitry and the control circuitry.

23. The method of claim 19, wherein the forming of a control circuitry comprises forming a selected circuitry of a circuitry group consisting of a timer circuitry adapted to determine idleness of the main circuitry and a control block adapted to synchronize the activation and deactivation of the main circuitry based on an external signal.

24. A method comprising:
receiving power by a control circuitry disposed on a control substrate; and
conditionally allowing the received power to be provided through the control circuitry to at least a portion of a main circuitry disposed on a main substrate stacked with the control substrate.

25. The method of claim 24, wherein said conditionally allowing comprises controlling any of a supply power voltage provided to at least a portion of the main circuitry with the control circuitry, an external ground coupled to at least a portion of the main circuitry with the control circuitry, and both a supply power voltage provided, and an external ground coupled to at least a portion of the main circuitry with the control circuitry.

26. The method of claim 24, wherein the control circuitry comprises a timer circuitry, and the conditionally allowing comprises determining whether the main circuitry is idle based at least in part on a state of the timer circuitry, the received power being allowed to be provided through the control circuitry when the main circuitry is determined to be non-idle.

27. The method of claim 24, wherein the control circuitry comprises a control block adapted to synchronize the activation and deactivation of the main circuitry based on an external signal, and the conditionally allowing comprises monitoring for the external signal, and the received power being allowed to be provided through the control circuitry when the external signal is present.
